(19) United States
(12) Patent Application Publication
(10) Pub. No.: US 2025/0211174 A1
(43) Pub. Date: Jun. 26, 2025

(54) DOHERTY AMPLIFIER

(71) Applicant: SAMSUNG ELECTRO-MECHANICS CO., LTD., Suwon-si (KR)

(72) Inventors: Geunyong LEE, Suwon-si (KR); Seungchul PYO, Suwon-si (KR); Suyeon HAN, Suwon-si (KR); Hyungjin LEE, Suwon-si (KR); Hyunjin YOO, Suwon-si (KR)

(73) Assignee: SAMSUNG ELECTRO-MECHANICS CO., LTD., Suwon-si (KR)

(21) Appl. No.: 18/769,333

(22) Filed: Jul. 10, 2024

(30) Foreign Application Priority Data
Dec. 20, 2023 (KR) 10-2023-0186855

(51) Int. Cl. H03F 1/02; H03F 3/24

(52) U.S. Cl. CPC H03F 1/0288; H03F 3/245; H03F 2200/451; H03F 2200/555

(57) ABSTRACT

A Doherty amplifier includes a carrier amplification transistor configured to amplify a first input radio frequency (RF) signal, a carrier bias circuit configured to supply a carrier bias voltage to the carrier amplification transistor, a peaking amplification transistor configured to amplify a second input RF signal, a peaking bias circuit configured to supply a peaking bias voltage to the peaking amplification transistor, and a first linearization circuit connected between a first terminal to which the second input RF signal is input and a second terminal to which the peaking bias voltage is output in the peaking bias circuit, and configured to couple a portion of the second input RF signal and provide the coupled portion to the second terminal.

### CROSS-REFERENCE TO RELATED APPLICATION

This application claims the benefit under 35 USC 119(a) of Korean Patent Application No. 10-2023-0186855 filed on Dec. 20, 2023, in the Korean Intellectual Property Office, the entire disclosure of which is incorporated herein by reference for all purposes.

### BACKGROUND

### 1. Field

The present disclosure relates to a Doherty amplifier.

### 2. Description of the Background

Wireless communication systems apply various digital modulation and demodulation schemes according to the evolution of communication standards. The existing code-division multiple access (CDMA) communication system adopts the quadrature phase-shift keying (QPSK) method, and the existing wireless LAN, following the IEEE communication standard, adopts the orthogonal frequency-division multiplexing (OFDM) method. In addition, long-term evolution (LTE) and LTE-Advanced, which are 3GPP standards, adopt QPSK, quadrature amplitude modulation (QAM), and OFDM schemes. These wireless communication standards adopt a linear modulation method that requires the magnitude or phase of a transmission signal to be maintained during transmission.

In the latest standards, e.g., 5G and sub-6, as the channel bandwidth becomes wider, the linearity of the power amplifier included in the communication system is becoming important. In addition, since these communication systems require high power, which is called power class 2, the linearity of power amplifiers is becoming more important.

One of the technologies for improving the efficiency of power amplifiers is the Doherty amplifier. These Doherty amplifiers may also require improvement of linearity.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a Doherty amplifier includes a carrier amplification transistor configured to amplify a first input radio frequency (RF) signal, a carrier bias circuit configured to supply a carrier bias voltage to the carrier amplification transistor, a peaking amplification transistor configured to amplify a second input RF signal, a peaking bias circuit configured to supply a peaking bias voltage to the peaking amplification transistor, and a first linearization circuit connected between a first terminal to which the second input RF signal is input and a second terminal to which the peaking bias voltage is output in the peaking bias circuit, and configured to couple a portion of the second input RF signal to the second terminal.

The peaking bias circuit may include a transistor configured to supply e the peaking bias voltage, and the second terminal may be an emitter of the transistor.

The Doherty amplifier may further include a resistor connected between the emitter of the transistor and an input terminal of the peaking amplification transistor.

A magnitude of a coupled signal coupled by the first linearization circuit may be changed according to a power mode.

The power mode may include a low-power mode and a high-power mode, and the magnitude of the coupled signal may be greater in the low-power mode than in the high-power mode.

The first linearization circuit may include a resistor and a capacitor coupled in series with each other between the first terminal and the second terminal.

The resistor may be a variable resistor, and a value of the variable resistor may be changed according to a power mode.

The power mode may include a low-power mode and a high-power mode, and the value of the variable resistor may be smaller in the low-power mode than in the high-power mode.

The first linearization circuit may include a resistor and a variable capacitor coupled in series with each other between the first terminal and the second terminal, and a value of the variable capacitor may be changed according to a power mode.

The power mode may include a low-power mode and a high-power mode, and the value of the variable capacitor may be greater in the low-power mode than in the high-power mode.

The Doherty amplifier may further include a second linearization circuit connected between a third terminal to which the first input RF signal is input and a fourth terminal to which the carrier bias voltage is output in the carrier bias circuit, and configured to couple a portion of the first input RF signal to the fourth terminal.

A magnitude of a coupled signal coupled by the first linearization circuit may be greater than a magnitude of a signal coupled by the second linearization circuit.

The first linearization circuit may include a first resistor and a first capacitor coupled in series with each other between the first terminal and the second terminal, and the second linearization circuit may include a second resistor and a second capacitor coupled in series with each other between the third terminal and the fourth terminal.

A value of the first resistor may be smaller than a value of the second resistor.

The Doherty amplifier may further include a power divider configured to generate the first input RF signal and the second input RF signal based on an input RF signal.

The carrier amplification transistor may be biased as Class AB by the carrier bias voltage, and the peaking amplification transistor may be biased as Class C by the peaking bias voltage.

In another general aspect, a Doherty amplifier includes a carrier amplification transistor configured to amplify a first input radio frequency (RF) signal, a first transistor including a first terminal configured to supply a carrier bias voltage to the carrier amplification transistor, a peaking amplification transistor configured to amplify a second input RF signal, a second transistor including a second configured to supply a peaking bias voltage to the peaking amplification transistor, and a first linearization circuit connected between a terminal to which the second input RF signal is input and the second terminal of the second transistor, and configured to couple a portion of the second input RF signal to the second terminal of the second transistor.

The Doherty amplifier may further include a second linearization circuit connected between a terminal to which the first input RF signal is input and the first terminal of the first transistor, and configured to couple a portion of the first input RF signal to the first terminal of the first transistor.

The first linearization circuit may include a first resistor and a first capacitor coupled in series with each other between the terminal to which the second input RF signal is input and the second terminal of the second transistor, and the second linearization circuit may include a second resistor and a second capacitor coupled in series with each other between the terminal to which the first input RF signal is input and the first terminal of the first transistor.

A value of the first resistor may be smaller than a value of the second resistor.

Other features and aspects will be apparent from the following detailed description, the drawings, and the claims.

### BRIEF DESCRIPTION OF DRAWINGS

FIG. 1 is a drawing showing a Doherty amplifier according to an embodiment.

FIG. 2A is a circuit diagram showing the carrier bias circuit of FIG. 1.

FIG. 2B is a circuit diagram showing the peaking bias circuit of FIG. 1.

FIG. 3A is a drawing showing an example of a linearization circuit 300_2.

FIG. 3B is a drawing showing another example of a linearization circuit 300_2.

FIG. 3C is a drawing showing another example of a linearization circuit 300_2.

FIG. 4 is a drawing showing another example of a linearization circuit 300_2.

FIG. 5 is a drawing showing an example of a variable resistor R3_VAR.

FIG. 6 is a drawing showing another example of a linearization circuit 300_2.

FIG. 7 is a drawing showing a Doherty amplifier according to another embodiment.

FIG. 8 is a drawing showing an example of a linearization circuit 300_1 and an example of a linearization circuit 300_2.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, an RF signal includes Wi-Fi (IEEE 802.11 family, etc.), WiMAX (IEEE 802.16 family, etc.), IEEE 802.20, LTE (long-term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited thereto.

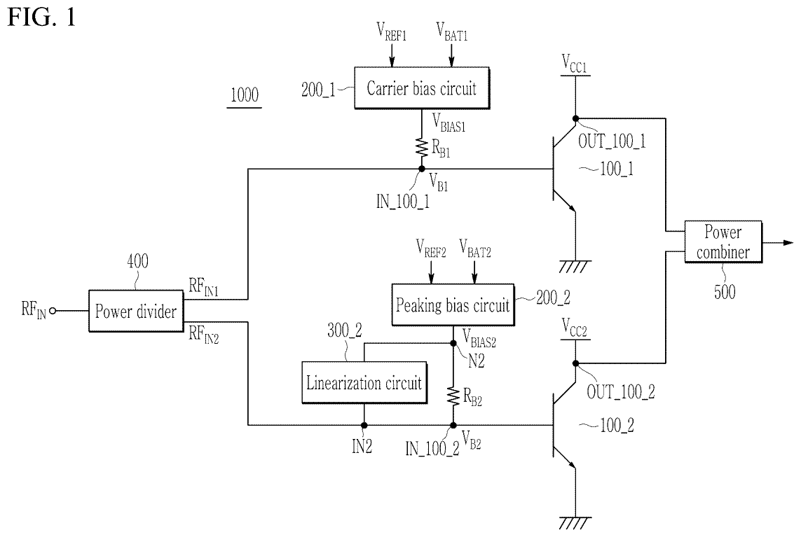

FIG. 1 is a drawing showing a Doherty amplifier 1000 according to an embodiment.

As shown in FIG. 1, the Doherty amplifier 1000, according to an embodiment, may include a carrier amplification transistor 100_1, a carrier bias circuit 200_1, a resistor R_{B1}, a peaking amplification transistor 100_2, a peaking bias circuit 200_2, a resistor R_{B2}, a linearization circuit 300_2, a power divider 400, and a power combiner 500.

In FIG. 1, the carrier amplification transistor 100_1, the carrier bias circuit 200_1, and the resistor R_{B1} may constitute a carrier amplifier, and the peaking amplification transistor 100_2, the peaking bias circuit 200_2, and the resistor R_{B2} may constitute a peaking amplifier. The carrier amplifier may operate regardless of the magnitude of an input RF signal RF_{IN}, and the peaking amplifier may operate when the magnitude of the input RF signal RF_{IN} is greater than a predetermined threshold value RF_{IN_TH}. That is, when the magnitude of the input RF signal RF_{IN} is the predetermined threshold value RF_{IN_TH} or less, the carrier amplifier operates, but the peaking amplifier does not operate. In addition, when the magnitude of the input RF signal RF_{IN} exceeds the predetermined threshold value RF_{IN_TH}, the carrier amplifier and the peaking amplifier may simultaneously operate. Through this, the Doherty amplifier 1000 may improve efficiency. Here, the magnitude of the input RF signal RF_{IN} may correspond to the peak voltage of the input RF signal RF_{IN}, or may correspond to the power of the input RF signal RF_{IN}.

The power divider 400 receives the input RF signal RF_{IN}, and may divide the input RF signal RF_{IN} into a first input RF signal RF_{IN1} and a second input RF signal RF_{IN2}. A specific configuration and operation of the power divider 400 will be apparent after understanding this disclosure; thus, a detailed description may be omitted. Here, the first input RF signal RF_{IN1} and the second input RF signal RF_{IN2} may have the same power as each other or may have different power. Meanwhile, when the peaking amplifier does not operate, the second input RF signal RF_{IN2} may not be generated, and the first input RF signal RF_{IN1} may have the same power as the input RF signal RF_{IN}.

The carrier amplification transistor 100_1 may include an input terminal IN_100_1 and an output terminal OUT_100_1. The input terminal IN_100_1 may be a base of the carrier amplification transistor 100_1, and the output terminal OUT_100_1 may be a collector of the carrier amplification transistor 100_1. The carrier amplification transistor 100_1 may amplify the power of an RF signal RF_{IN1} input to the input terminal IN_100_1 (e.g., base), and may output the amplified signal to the output terminal OUT_100_1 (e.g., collector). That is, an RF signal to be amplified is input through the base of the carrier amplification transistor 100_1, and an amplified RF signal may be output through the collector of the carrier amplification transistor 100_1. Meanwhile, in FIG. 1, the base of the carrier amplification transistor 100_1 voltage is denoted as “V_{B1}”.

An emitter of the carrier amplification transistor 100_1 may be connected to the ground. Although not illustrated in FIG. 1, a resistor may be additionally connected between the emitter of the carrier amplification transistor 100_1 and the ground. In addition, the collector of the carrier amplification transistor 100_1 may be connected to a power source voltage V_{CC1}, and the carrier amplification transistor 100_1 may be operated by the power source voltage V_{CC1}. Meanwhile, the collector of the carrier amplification transistor 100_1 may be connected to the power source voltage V_{CC1} through an inductor (not shown in FIG. 1) performing an RF choke function.

The carrier amplification transistor 100_1 may be realized as various transistors such as a heterojunction bipolar transistor (HBT), a bipolar junction transistor (BJT), and an insulated gate bipolar transistor (IGBT). In addition, although the carrier amplification transistor 100_1 is illustrated as an N-type in FIG. 1, it may be replaced with a P-type.

Meanwhile, although not illustrated in FIG. 1, a coupling capacitor may be located between the power divider 400 and the input terminal IN_100_1 of the carrier amplification transistor 100_1. The coupling capacitor may perform the function of removing (i.e., blocking) the direct current (DC) component from an RF signal.

The carrier bias circuit 200_1 may be supplied with a reference voltage V_{REF1} and a power source voltage V_{BAT1} from the outside. Here, the power source voltage V_{BAT1} may be a voltage supplied from a battery. Meanwhile, the power source voltage V_{BAT1} may be the same voltage as the reference voltage V_{REF1}. The carrier bias circuit 200_1 may generate a carrier bias voltage V_{BIAS1} by using the reference voltage VREF, and the power source voltage V_{BAT1}. The carrier bias voltage V_{BIAS1} may be supplied to the input terminal IN_100_1 of the carrier amplification transistor 100_1 through the resistor R_{B1}, and the carrier amplification transistor 100_1 a bias level (i.e., a bias point) may be set by the carrier bias voltage V_{BIAS1}.

Such that the carrier amplification transistor 100_1 may be biased as Class AB, the carrier bias circuit 200_1 may generate the carrier bias voltage V_{BIAS1}. That is, by the carrier bias voltage V_{BIAS1}, the carrier amplification transistor 100_1 is biased as Class AB. Because the carrier amplification transistor 100_1 is biased as Class AB, the carrier amplification transistor 100_1 may perform the amplification operation regardless of the magnitude of the input RF signal RF_{IN}.

The resistor R_{B1} may be connected between the carrier bias circuit 200_1 and the input terminal IN_100_1 of the carrier amplification transistor 100_1. Here, the resistor R_{B1} may be a ballast resistor that improves the heat dissipation characteristics of the Doherty amplifier 1000. Although FIG. 1 illustrates the resistor R_{B1} as a separate component not included in the carrier bias circuit 200_1, the resistor RB1 may be included in the carrier bias circuit 200_1. Meanwhile, a voltage drop occurs due to the resistor R_{B1}, and accordingly, a base voltage V_{B1} of the carrier amplification transistor 100_1 may be a voltage lower than the carrier bias voltage V_{BIAS1}.

The peaking amplification transistor 100_2 may include an input terminal IN_100_2 and an output terminal OUT_100_2. The input terminal IN_100_2 may be a base of the peaking amplification transistor 100_2, and the output terminal OUT_100_2 may be a collector of the peaking amplification transistor 100_2. The peaking amplification transistor 100_2 may amplify the power of the RF signal RF_{IN2} input to the input terminal IN_100_2 (e.g., base), and may output the amplified signal to the output terminal OUT_100_2 (e.g., collector). That is, an RF signal to be amplified is input through the base of the peaking amplification transistor 100_2, and an amplified RF signal may be output through the collector of the peaking amplification transistor 100_2. Meanwhile, in FIG. 1, a terminal to which the second input RF signal RF_{IN2} is input is denoted as ‘IN2’, and the base of the peaking amplification transistor 100_2 voltage is denoted as “V_{B2}”.

An emitter of the peaking amplification transistor 100_2 may be connected to the ground, and although not illustrated in FIG. 1, a resistor may be additionally connected between the emitter of the peaking amplification transistor 100_2 and the ground. In addition, the collector of the peaking amplification transistor 100_2 may be connected to a power source voltage V_{CC2}, and the peaking amplification transistor 100_2 may be operated by the power source voltage V_{CC2}. Meanwhile, the collector of the peaking amplification transistor 100_2 may be connected to the power source voltage V_{CC2} through an inductor (not shown in FIG. 1) performing an RF choke function.

The peaking amplification transistor 100_2 may be realized as various transistors such as a heterojunction bipolar transistor (HBT), a bipolar junction transistor (BJT), and an insulated gate bipolar transistor (IGBT). In addition, although the peaking amplification transistor 100_2 is illustrated as an N-type in FIG. 1, it may be replaced with a P-type.

Meanwhile, although not illustrated in FIG. 1, a coupling capacitor may be located between the power divider 400 and the input terminal IN_100_2 of the peaking amplification transistor 100_2. That is, a coupling capacitor may be located between a terminal IN2 to which the second input RF signal RF_{IN2} is input and the input terminal IN_100_2 of the peaking amplification transistor 100_2. The coupling capacitor may perform the function of removing (i.e., blocking) the direct current (DC) component from an RF signal.

The peaking bias circuit 200_2 may be supplied with a reference voltage V_{REF2} and a power source voltage V_{BAT2} from the outside. Here, the power source voltage V_{BAT2} may be a voltage supplied from a battery. Meanwhile, the power source voltage V_{BAT2} may be the same voltage as the reference voltage V_{REF2}. The peaking bias circuit 200_2 may generate a peaking bias voltage V_{BIAS2} by using the reference voltage V_{REF2} and the power source voltage V_{BAT2}. The peaking bias voltage V_{BIAS2} may be supplied to the input terminal IN_100_2 of the peaking amplification transistor 100_2 through the resistor R_{B2}, and the peaking amplification transistor 100_2 a bias level (i.e., a bias point) may be set by the peaking bias voltage V_{BIAS2}.

The peaking amplification transistor 100_2 may be biased as Class C, and the peaking bias circuit 200_2 may generate the peaking bias voltage V_{BIAS2}. That is, by the peaking bias voltage V_{BIAS2}, the peaking amplification transistor 100_2 is biased as Class C. Because the peaking amplification transistor 100_2 is biased as Class C, the peaking amplification transistor 100_2 may operate when the magnitude of the input RF signal RF_{IN} is greater than the predetermined threshold value RF_{IN_TH}.

The resistor R_{B2} may be connected between the peaking bias circuit 200_2 and the input terminal IN_100_2 of the peaking amplification transistor 100_2. Here, the resistor R_{B2} may be a ballast resistor that improves the heat dissipation characteristics of the Doherty amplifier 1000. Although FIG. 1 illustrates the resistor R_{B2} as a separate component not included in the peaking bias circuit 200_2, the resistor RB2 may be included in the peaking bias circuit 200_2. Meanwhile, a voltage drop occurs due to the resistor R_{B2}, and accordingly, a base voltage V_{B2} of the peaking amplification transistor 100_2 may be a voltage lower than the peaking bias voltage V_{BIAS2}.

The power combiner 500 may receive the output RF signal of the carrier amplification transistor 100_1 and the output RF signal of the peaking amplification transistor 100_2, and may combine the two signals. Meanwhile, the power combiner 500 may include an impedance inverter. The impedance inverter may perform a phase transition of 90 degrees on the output RF signal of the carrier amplification transistor 100_1. In addition, when the peaking amplification transistor 100_2 does not operate, the impedance inverter may perform impedance matching. That is, the impedance inverter may be designed to provide a phase offset of 90 degrees and impedance matching. A specific configuration and operation of the power combiner 500 will be apparent after an understanding of the disclosure of this application, and thus, a detailed description thereof may be omitted. Meanwhile, when the power combiner 500 provides a phase transition of 90 degrees on the output RF signal of the carrier amplification transistor 100_1, although not shown illustrated in FIG. 1, a 90-degree phase converter may be located between the power divider 400 and the input terminal IN_100_2 of the peaking amplification transistor 100_2.

Meanwhile, the peaking bias voltage V_{BIAS2} may be set at a level lower than the carrier bias voltage V_{BIAS1}. That is, in order for the peaking amplification transistor 100_2 to be biased to Class C and for the carrier amplification transistor 100_1 to be biased to Class AB, the peaking bias voltage V_{BIAS2} may be set to a voltage lower than the carrier bias voltage V_{BIAS1}. As an example, the peaking bias voltage V_{BIAS2} may be 0.7V, and the carrier bias voltage V_{BIAS1} may be 1.2V. In addition, by the resistor R_{B1}, the base voltage V_{B1} of the carrier amplification transistor 100_1 may decrease, and by the resistor R_{B2}, the base voltage V_{B2} of the peaking amplification transistor 100_2 may decrease. This phenomenon, called a base voltage drop, will be apparent after understanding the disclosure of this application, and thus, a detailed description may be omitted. Because the peaking bias voltage V_{BIAS2} is lower than the carrier bias voltage V_{BIAS1}, the base voltage V_{B2} of the peaking amplification transistor 100_2 may be more problematic. Accordingly, in the magnitude of the input RF signal RF_{IN} in which the carrier amplifier and the peaking amplifier simultaneously operate, the RF characteristics may be changed and generated and the linearity of the Doherty amplifier 1000 may be affected. In order to improve this, the Doherty amplifier 1000, according to an embodiment, may further include the linearization circuit 300_2 located in the peaking amplifier. The linearization circuit 300_2 may couple a partial signal among the second input RF signal RF_{IN2} input to the input terminal IN_100_2 of the peaking amplification transistor 100_2, and output the coupled signal to a node N2. Hereinafter, the partial signal coupled by the linearization circuit 300_2 is referred to as ‘the coupled input RF signal’. A specific configuration and operation of the linearization circuit 300_2 will be described in further detail hereinafter.

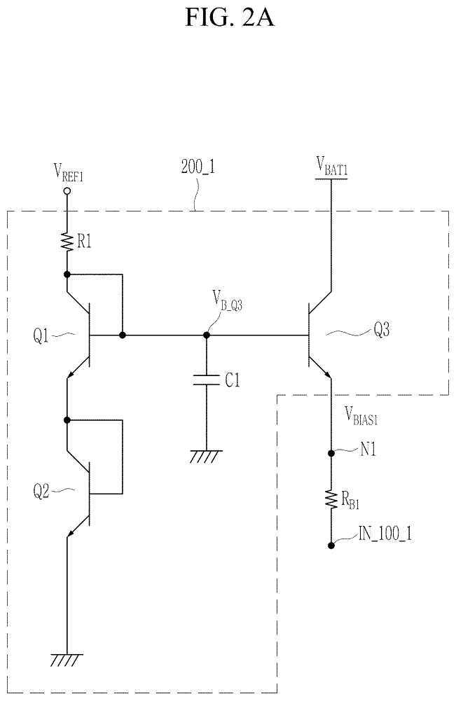

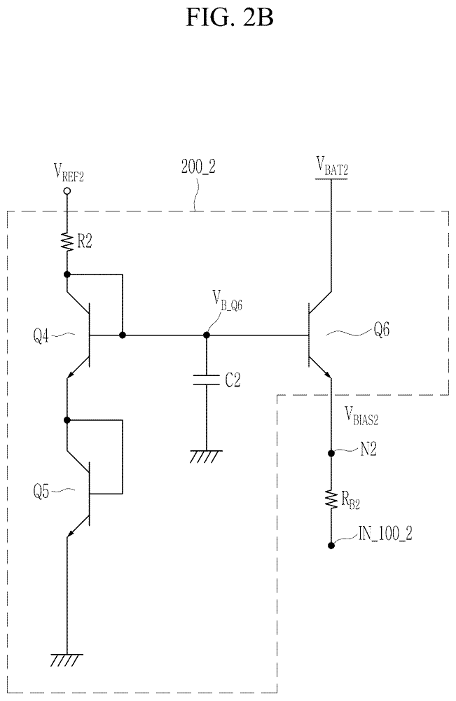

FIG. 2A is a circuit diagram showing the carrier bias circuit 200_1 of FIG. 1.

As shown in FIG. 2A, the carrier bias circuit 200_1 may include a transistor Q1, a transistor Q2, a transistor Q3, a resistor R1, and a capacitor C1.

The transistors Q1 to Q3 may be realized as various transistors, such as a heterojunction bipolar transistor (HBT), a bipolar junction transistor (BJT), and an insulated gate bipolar transistor (IGBT). In addition, although the transistors Q1 to Q3 are illustrated as an N-type in FIG. 2A, they may be replaced with a P-type. Meanwhile, the bases of the transistors Q1 to Q3 may act as a control terminal, and thus may be referred to as the term ‘control terminal’. Collectors of the transistors Q1 to Q3 are terminals of a transistor, and thus each of them may be referred to as a ‘first terminal’ or ‘second terminal’. In addition, emitters of the transistors Q1 to Q3 are also terminals of a transistor, and thus each of them may be referred to as a ‘second terminal’ or ‘first terminal’.

The base and the collector of the transistor Q1 may be connected to each other, and the collector of the transistor Q1 may receive the reference voltage V_{REF1} through the resistor R1. Here, the transistor Q1 may have a diode-connection structure.

The base and the collector of the transistor Q2 may be connected to each other, and the collector of the transistor Q2 may be connected to the emitter of the transistor Q1. The transistor Q2 may have a diode-connection structure, and the emitter of the transistor Q2 may be connected to the ground. Meanwhile, although not illustrated in FIG. 2A, a resistor may be added between the emitter of the transistor Q2 and the ground.

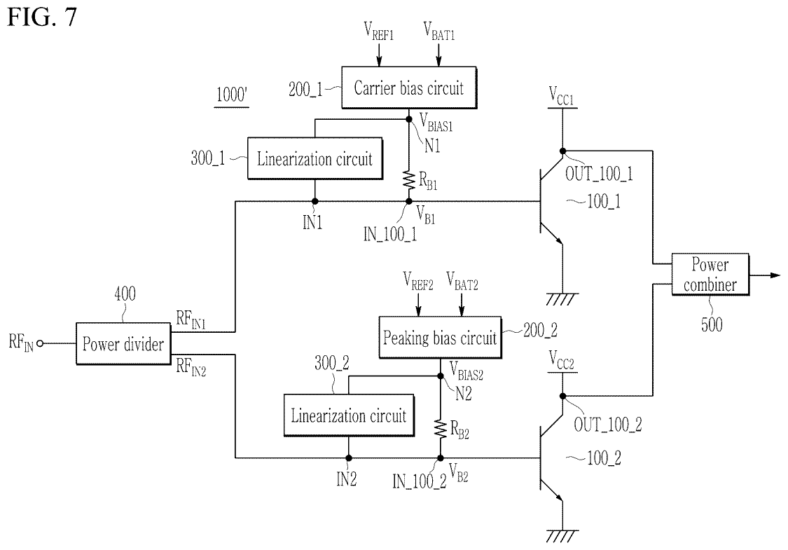

The collector of the transistor Q3 may be connected to the power source voltage V_{BAT1}, and the base of the transistor Q3 may be connected to the base of the transistor Q1. In FIG. 2A, the base of the transistor Q3 voltage is denoted as ‘V_{B_Q3}’. In addition, the emitter of the transistor Q3 may be connected to the input terminal IN_100_1 of the carrier amplification transistor 100_1 through the resistor R_{B1}. That is, the emitter of the transistor Q3 may supply the carrier bias voltage V_{BIAS1} to the carrier amplification transistor 100_1 through the resistor R_{B1}. Meanwhile, the node where the emitter of the transistor Q3 and the resistor R_{B1} are connected to each other may be a node N1 in FIG. 7 below.

The capacitor C1 may be connected between the base of the transistor Q3 and the ground. The capacitor C1 may serve to stabilize a base voltage V_{B_Q3} of the transistor Q3, and at the same time, may server to decrease the impedance of the transistor Q3.

The reference voltage V_{REF1} may be distributed by the resistor R1, the transistor Q1, and the transistor Q2, and through this, the base voltage V_{B_Q3} of the transistor Q3 may be determined. The carrier bias voltage V_{BIAS1} may be determined based on the base voltage V_{B_Q3} of the transistor Q3. As an example, when the base voltage V_{B_Q3} of the transistor Q3 is raised, the carrier bias voltage V_{BIAS1} may be raised.

FIG. 2B is a circuit diagram showing the peaking bias circuit 200_2 of FIG. 1.

As shown in FIG. 2B, the peaking bias circuit 200_2 may include a transistor Q4, a transistor Q5, transistor Q36, a resistor R2, and a capacitor C2.

The transistors Q4 to Q6 may be realized as various transistors, such as a heterojunction bipolar transistor (HBT), a bipolar junction transistor (BJT), and an insulated gate bipolar transistor (IGBT). In addition, although the transistors Q4 to Q6 are illustrated as an N-type in FIG. 2B, they may be replaced with a P-type. Meanwhile, the bases of the transistors Q4 to Q6 may act as a control terminal, and thus may be referred to as the term ‘control terminal’. Collectors of the transistors Q4 to Q6 are terminals of a transistor, and thus each of them may be referred as a ‘first terminal’ or ‘second terminal’. In addition, emitters of the transistors Q4 to Q6 are also terminals of a transistor, and thus each of them may be referred as a ‘second terminal’ or ‘first terminal’.

The base and the collector of the transistor Q4 may be connected to each other, and the collector of the transistor Q4 may receive the reference voltage V_{REF2} through the resistor R2. Here, the transistor Q4 may have a diode-connection structure.

The base and the collector of the transistor Q5 may be connected to each other, and the collector of the transistor Q5 may be connected to the emitter of the transistor Q4. The transistor Q5 may have a diode-connection structure, and the emitter of the transistor Q5 may be connected to the ground. Meanwhile, although not illustrated in FIG. 2B, a resistor may be added between the emitter of the transistor Q5 and the ground.

A collector of a transistor Q6 may be connected to the power source voltage V_{BAT2}, and the base of the transistor Q6 may be connected to the base of the transistor Q4. In FIG. 2B, the base of the transistor Q6 voltage is denoted as ‘V_{B_Q6}’. In addition, the emitter of the transistor Q6 may be connected to the input terminal IN_100_2 of the peaking amplification transistor 100_2 through the resistor R_{B2}. That is, the emitter of the transistor Q6 may supply the peaking bias voltage V_{BIAS2} to the peaking amplification transistor 100_2 through the resistor R_{B2}. Meanwhile, a node where the emitter of the transistor Q6 and the resistor R_{B2} are connected to each other is denoted as the node N2.

The capacitor C2 may be connected between the base of the transistor Q6 and the ground. The capacitor C2 may serve to stabilize a base voltage V_{B_Q6} of the transistor Q6, and at the same time, may server to decrease the impedance of the transistor Q6.

The reference voltage V_{REF2} may be distributed by the resistor R2, the transistor Q4, and the transistor Q5, and through this, the base voltage V_{B_Q6} of the transistor Q6 may be determined. The peaking bias voltage V_{BIAS2} may be determined based on the base voltage V_{B_Q6} of the transistor Q6. As an example, the base voltage V_{B_Q6} of when the transistor Q6 is raised, the peaking bias voltage V_{BIAS2} may be raised.

As described above, the linearization circuit 300_2 may output the coupled input RF signal to the node N2. The coupled input RF signal may be input to the emitter of the transistor Q6, and accordingly, the peaking bias voltage V_{BIAS2} may be raised. As the peaking bias voltage V_{BIAS2} is raised, the base of the peaking amplification transistor 100_2 voltage may be raised. That is, by the linearization circuit 300_2, the base of the peaking amplification transistor 100_2 voltage may increase.

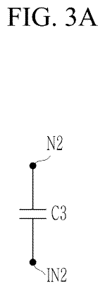

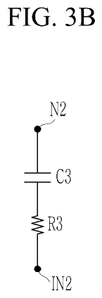

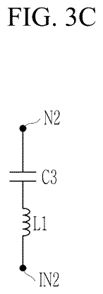

Hereinafter, various examples of the linearization circuit 300_2 will be described in detail with reference to FIG. 3A to FIG. 3C below.

FIG. 3A is a drawing showing an example of the linearization circuit 300_2.

As shown in FIG. 3A, an example of the linearization circuit 300_2 may include a capacitor C3. The capacitor C3 may be connected between the terminal IN2 to which the second input RF signal RF_{IN2} is input and the node N2. The capacitor C2 may couple a partial signal among the second input RF signal RF_{IN2}, and may output the coupled signal to the node N2.

FIG. 3B is a drawing showing another example of the linearization circuit 300_2.

As shown in FIG. 3B, another example of the linearization circuit 300_2 may include the capacitor C3 and a resistor R3. A first end of the resistor R3 may be connected to the terminal IN2 to which the second input RF signal RF_{IN2} is input, and the capacitor C3 may be connected between a second end of the resistor R3 and the node N2. Meanwhile, unlike FIG. 3B, locations of the resistor R3 and the capacitor C3 may be interchanged. That is, a first end of the capacitor C3 may be connected to the terminal IN2 to which the second input RF signal RF_{IN2} is input, and the resistor R3 may be connected between a second end of the capacitor C3 and the node N2.

In other words, the resistor R3 and the capacitor C3 may be coupled in series with each other between the terminal IN2 to which the second input RF signal RF_{IN2} is input and the node N2. The resistor R3 and the capacitor C3 may couple a partial signal among the second input RF signal RF_{IN2}, and may output the coupled signal to the node N2.

FIG. 3C is a drawing showing the still another example of a linearization circuit 300_2.

As shown in FIG. 3C, still another example of the linearization circuit 300_2 may include the capacitor C3 and an inductor L1. A first end of the inductor L1 may be connected to the terminal IN2 to which the second input RF signal RF_{IN2} is input, and the capacitor C3 may be connected between a second end of the inductor L1 and the node N2. Meanwhile, unlike FIG. 3C, locations of the inductor L1 and the capacitor C3 may be interchanged. That is, the first end of the capacitor C3 may be connected to the terminal IN2 to which the second input RF signal RF_{IN2} is input, and the inductor L1 may be connected between the second end of the capacitor C3 and the node N2.

In other words, the inductor L1 and the capacitor C3 may be coupled in series with each other between the terminal IN2, to which the second input RF signal RF_{IN2} is input, and the node N2. The inductor L1 and the capacitor C3 may couple a partial signal among the second input RF signal RF_{IN2}, and may output the coupled signal to the node N2.

Meanwhile, according to the magnitude of the coupled input RF signal, the degree compensation for the base voltage drop of the peaking amplification transistor 100_2 may vary. The larger the coupled input RF signal, the more the base voltage drop of the peaking amplification transistor 100_2 may be compensated.

Meanwhile, in FIG. 1, in order to improve the efficiency of the peaking amplifier, the value of the power source voltage V_{CC2} may be changed depending on the power mode. As an example, the power mode may include a high-power mode (HPM) and a low-power mode (LPM). The value of the power source voltage V_{CC2} may be set to a lower value in the low-power mode (LPM) than in the high-power mode (HPM). As the value of the power source voltage V_{CC2} decreases, the linearity of the peaking amplifier may be worse. As an example, the linearity of the peaking amplifier may be worse in the low-power mode (LPM) than in the high-power mode (HPM).

Accordingly, the linearization circuit 300_2 may adjust the coupling magnitude (amount) with respect to the second input RF signal RF_{IN2}, depending on the power mode. That is, the coupled input RF signal output from the linearization circuit 300_2 may have different magnitudes (amounts) depending on the power mode. Here, the magnitude of the coupled input RF signal may be a power of the coupled input RF signal.

As an example, the coupling magnitude (magnitude of the coupled input RF signal) of the linearization circuit 300_2 may be greater in the low-power mode (LPM) than in the high-power mode (HPM). That is, the magnitude of the coupled input RF signal may have the relationship of Equation 1 below, depending on the power mode.

$${COUPLED\_RF}_{IN 2} \_LPM > {COUPLED\_RF}_{IN 2} \_HPM \qquad Equation 1$$

In Equation 1, COUPLED_RF_{IN2}_LPM represents the magnitude of the coupled input RF signal in the low-power mode, and COUPLED_RF_{IN2}_HPM represents the magnitude of the coupled input RF signal in the high-power mode.

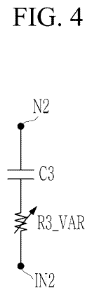

Through this, the linearization circuit 300_2, according to an embodiment, may compensate for the deterioration in linearity as the power mode is lowered. The method for the linearization circuit 300_2 to adjust the coupling magnitude with respect to the second input RF signal RF_{IN2} depending on the power mode will be described in detail with reference to FIG. 4.

FIG. 4 is a drawing showing still another example of the linearization circuit 300_2.

As shown in FIG. 4, still another example of the linearization circuit 300_2 may include a variable resistor R3_VAR and the capacitor C3. That is, the linearization circuit of FIG. 4 is formed by replacing the resistor R3 with the variable resistor R3_VAR from the linearization circuit of FIG. 3B.

According to a value of the variable resistor R3_VAR, the magnitude of the coupled input RF signal may be changed. As the value of the variable resistor R3_VAR decreases, the magnitude of the coupled input RF signal may increase. That is, since the resistor attenuates the RF signal, the magnitude of the coupled input RF signal may be adjusted by adjusting the value of the variable resistor R3_VAR.

The variable resistor R3_VAR may be changed depending on the power mode. As an example, the value of the variable resistor R3_VAR may be smaller in the low-power mode (LPM) than in the high-power mode (HPM). That is, the value of the variable resistor R3_VAR may have the relationship of Equation 2 below, depending on the power mode.

$$R3\_VAR \_LPM < R3\_VAR \_HPM \qquad Equation 2$$

In Equation 3, R3_VAR_LPM represents the value of the variable resistor R3_VAR in the low-power mode (LPM), and R3_VAR_HPM represents the value of the variable resistor R3_VAR in the high-power mode (HPM).

Meanwhile, the method of changing the value of the variable resistor R3_VAR depending on the power mode may be implemented in various ways. Hereinafter, as an example, a method of changing the value of the variable resistor R3_VAR by a switch will be described.

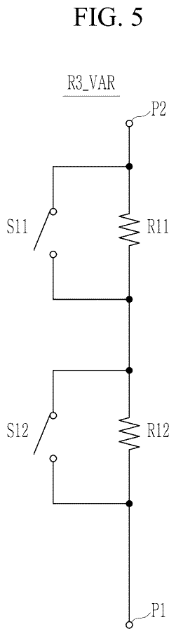

FIG. 5 is a drawing showing an example of the variable resistor R3_VAR.

As shown in FIG. 5, the variable resistor R3_VAR may include a resistor R11, a resistor R12, a switch S11, and a switch S12. A terminal P1 may be a first end of the variable resistor R3_VAR, and a terminal P2 may be a second end of the variable resistor R3_VAR.

The resistor R11 and the resistor R12 may be coupled in series with each other between the two terminals P1 and P2. That is, a first end of the resistor R11 may be connected to the terminal P2, and the resistor R12 may be connected between a second end of the resistor R11 and a terminal P1.

The switch S11 may be coupled in parallel to the both ends of the resistor R11, and the switch S12 may be coupled in parallel to the both ends of the resistor R12. The switch S11 and the switch S12 may be switched depending on the power mode.

In the low-power mode (LPM), one switch of switches S11 and S12 may be turned on and the other switch may be turned off. As an example, the switch S12 may be turned on and the switch S11 may be turned off, and through this, a value of the resistor R11 may become the value of the variable resistor R3_VAR.

In the high-power mode (HPM), all of the switches S11 and S12 may be turned off. Accordingly, a sum of the value of the resistor R11 and the value of the resistor R12 may become the value of the variable resistor R3_VAR.

Although FIG. 5 explains a method of changing the value of the variable resistor R3_VAR depending on the power mode by using two resistors and two switches, it may also be implemented through three resistors and three switches. In addition, the value of the variable resistor R3_VAR depending on the power mode may be changed by using four or more resistors and four or more switches. Meanwhile, although an example of two power modes is explained with reference to FIG. 5, the method may also be applied to three power modes (e.g., LPM, middle power mode (MPM), HPM). Such examples will be apparent after understanding the disclosure of this application, and thus, a detailed description thereof may be omitted.

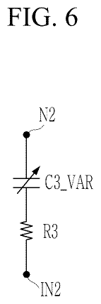

FIG. 6 is a drawing showing still another example of the linearization circuit 300_2.

As shown in FIG. 6, still another example of the linearization circuit 300_2 may include the resistor R3 and a variable capacitor C3_VAR. That is, the linearization circuit of FIG. 6 is formed by replacing the capacitor C3 with variable capacitor C3_VAR from the linearization circuit of FIG. 3B.

According to a value of the variable capacitor C3_VAR, the magnitude of the coupled input RF signal may be changed. As the value of the variable capacitor C3_VAR increases, the magnitude of the coupled input RF signal may increase. That is, the magnitude of the coupled input RF signal may be adjusted by adjusting the value of the variable capacitor C3_VAR.

The variable capacitor C3_VAR may be changed depending on the power mode. As an example, the value of the variable capacitor C3_VAR may be greater in the low-power mode (LPM) than in the high-power mode (HPM). That is, the value of the variable capacitor C3_VAR may have the relationship of Equation 3 below, depending on the power mode.

$$C3\_VAR \_LPM > C3\_VAR \_HPM \qquad Equation 3$$

In Equation 3, C3_VAR_LPM represents the value of the variable capacitor C3_VAR in the low-power mode (LPM), and C3_VAR_HPM represents the value of the variable capacitor C3_VAR in the high-power mode (HPM).

Meanwhile, the variable capacitor C3_VAR may be implemented by using a varactor diode. In addition, the variable capacitor C3_VAR may be implemented through a plurality of capacitors and a plurality of switches, similar to the method of FIG. 5.

FIG. 7 is a drawing showing a Doherty amplifier 1000′ according to another embodiment.

As shown in FIG. 7, the Doherty amplifier 1000′ according to another embodiment may include the carrier amplification transistor 100_1, the carrier bias circuit 200_1, the resistor R_{B1}, a linearization circuit 300_1, the peaking amplification transistor 100_2, the peaking bias circuit 200_2, the resistor R_{B2}, the linearization circuit 300_2, the power divider 400, and the power combiner 500. The Doherty amplifier 1000′ of FIG. 7 is similar to the Doherty amplifier 1000 of FIG. 1 except that the linearization circuit 300_1 is added, and thus the redundant description is not included herein. In FIG. 7, the terminal to which the first input RF signal RF_{IN1} is input is denoted as ‘IN1’.

Meanwhile, although not illustrated in FIG. 7, a coupling capacitor may be located between the power divider 400 and the input terminal IN_100_1 of the carrier amplification transistor 100_1. That is, a coupling capacitor may be located between a terminal IN1 to which the first input RF signal RF_{IN1} is input and the input terminal IN_100_1 of the carrier amplification transistor 100_1. The coupling capacitor may perform the function of removing (i.e., blocking) the direct current (DC) component from an RF signal.

By the resistor R_{B1}, the base voltage V_{B1} of the carrier amplification transistor 100_1 may decrease. In order to solve this, the Doherty amplifier 1000′ may further include the linearization circuit 300_1 located in the carrier amplifier. The linearization circuit 300_1 may couple a partial signal among the first input RF signal RF_{IN1} input to the input terminal IN_100_1 of the carrier amplification transistor 100_1, and output the coupled signal to the node N1. The coupled input RF signal may be input to the emitter of the transistor Q3 of FIG. 2A, and accordingly, the carrier bias voltage V_{BIAS1} may be raised. As the carrier bias voltage V_{BIAS1} is raised, a base voltage drop of the carrier amplification transistor 100_1 may be compensated for. That is, the linearization circuit 300_1 may compensate for a base voltage drop of the carrier amplification transistor 100_1.

A specific internal circuit of the linearization circuit 300_1 may correspond to one of FIG. 3A to FIG. 3C, FIG. 4, and FIG. 6.

As described with reference to FIG. 1, in order for the peaking amplification transistor 100_2 to be biased to Class C and for the carrier amplification transistor 100_1 to be biased to Class AB, the peaking bias voltage V_{BIAS2} may be set to a voltage lower than the carrier bias voltage V_{BIAS1}. Because the peaking bias voltage V_{BIAS2} is lower than the carrier bias voltage V_{BIAS1}, the base voltage V_{B2} of the peaking amplification transistor 100_2 may be more problematic. As the magnitude of the coupled input RF signal increases, the base voltage may increase. Accordingly, the magnitude of the coupled input RF signal output from the linearization circuit 300_2 may be greater than the magnitude of the coupled input RF signal output from the linearization circuit 300_1.

That is, the magnitude of the coupled input RF signal output from the linearization circuit 300_1 and the magnitude of the coupled input RF signal output from the linearization circuit 300_2 may have the relationship of Equation 4 below.

$${COUPLED\_RF}_{IN 1} < {COUPLED\_RF}_{IN 2} \qquad Equation 4$$

In Equation 4, COUPLED_RF_{IN1} represents the magnitude of the coupled input RF signal output from the linearization circuit 300_1, and COUPLED_RF_{IN2} represents the magnitude of the coupled input RF signal output from the linearization circuit 300_2.

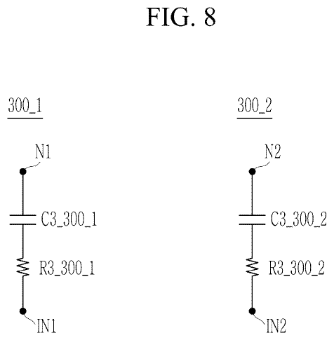

FIG. 8 is a drawing showing an example of the linearization circuit 300_1 and an example of the linearization circuit 300_2.

The linearization circuit 300_1 may include a resistor R3_300_1 and a capacitor C3_300_1. The resistor R3_300_1 and the capacitor C3_300_1 may be coupled in series with each other between the terminal IN1 to which the first input RF signal RF_{IN1} is input and the node N1. The resistor R3_300_1 and the capacitor C3_300_1 may couple a partial signal among the first input RF signal RF_{IN1}, and may output the coupled signal to the node N1.

The linearization circuit 300_2 may include a resistor R3_300_2 and a capacitor C3_300_2. The resistor R3_300_2 and the capacitor C3_300_2 may be coupled in series with each other between the terminal IN2 to which the second input RF signal RF_{IN2} is input, and the node N2. The resistor R3_300_2 and the capacitor C3_300_2 may couple a partial signal among the second input RF signal RF_{IN2}, and may output the coupled signal to the node N2.

Meanwhile, as an example for satisfying the relationship of Equation 4, a value of the resistor R3_300_1 and a value of the resistor R3_300_2 may have the relationship of Equation 5 below. Here, a value of the capacitor C3_300_1 and a value of a capacitor C300_2 may have the same value.

$$R3\_ 300 \_ 1 > R3\_ 300 \_ 2 \qquad Equation 5$$

Since the resistor attenuates the RF signal, the value of the resistor R3_300_2 may be smaller than the value of the resistor R3_300_1.

As another example for satisfying the relationship of Equation 4, a value of a capacitor C_300_1 and a value of the capacitor C3_300_2 may have the relationship of Equation 6 below. Here, the value of the resistor R3_300_1 and the value of the resistor R3_300_2 may have the same value.

$$C3\_ 300 \_ 1 < C3\_ 300 \_ 2 \qquad Equation 6$$

Since the magnitude of the coupled input RF signal increases as the capacitance value increases, the value of the capacitor C3_300_2 may be greater than the value of the capacitor C3_300_1.

The present disclosure attempts to provide a Doherty amplifier with improved linearity.

In one or more embodiments, the linearity of the Doherty amplifier may be improved by applying a linearization circuit.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A Doherty amplifier, comprising:
a carrier amplification transistor configured to amplify a first input radio frequency (RF) signal;
a carrier bias circuit configured to supply a carrier bias voltage to the carrier amplification transistor;
a peaking amplification transistor configured to amplify a second input RF signal;
a peaking bias circuit configured to supply a peaking bias voltage to the peaking amplification transistor; and
a first linearization circuit connected between a first terminal to which the second input RF signal is input and a second terminal to which the peaking bias voltage is output in the peaking bias circuit, and configured to couple a portion of the second input RF signal to the second terminal.

2. The Doherty amplifier of claim 1, wherein
the peaking bias circuit comprises a transistor configured to supply the peaking bias voltage, and
the second terminal is an emitter of the transistor.

3. The Doherty amplifier of claim 2, further comprising a resistor connected between the emitter of the transistor and an input terminal of the peaking amplification transistor.

4. The Doherty amplifier of claim 1, wherein a magnitude of a coupled signal coupled by the first linearization circuit is changed according to a power mode.

5. The Doherty amplifier of claim 4, wherein
the power mode comprises a low-power mode and a high-power mode, and
the magnitude of the coupled signal is greater in the low-power mode than in the high-power mode.

6. The Doherty amplifier of claim 1, wherein the first linearization circuit comprises a resistor and a capacitor coupled in series with each other between the first terminal and the second terminal.

7. The Doherty amplifier of claim 6, wherein
the resistor is a variable resistor, and
a value of the variable resistor is changed according to a power mode.

8. The Doherty amplifier of claim 7, wherein
the power mode comprises a low-power mode and a high-power mode, and
the value of the variable resistor is smaller in the low-power mode than in the high-power mode.

9. The Doherty amplifier of claim 1, wherein
the first linearization circuit comprises a resistor and a variable capacitor coupled in series with each other between the first terminal and the second terminal; and
a value of the variable capacitor is changed according to a power mode.

10. The Doherty amplifier of claim 9, wherein:
the power mode comprises a low-power mode and a high-power mode and
the value of the variable capacitor is greater in the low-power mode than in the high-power mode.

11. The Doherty amplifier of claim 1, further comprising a second linearization circuit connected between a third terminal to which the first input RF signal is input and a fourth terminal to which the carrier bias voltage is output in the carrier bias circuit, and configured to couple a portion of the first input RF signal to the fourth terminal.

12. The Doherty amplifier of claim 11, wherein a magnitude of a coupled signal coupled by the first linearization circuit is greater than a magnitude of a signal coupled by the second linearization circuit.

13. The Doherty amplifier of claim 11, wherein
the first linearization circuit comprises a first resistor and a first capacitor coupled in series with each other between the first terminal and the second terminal, and
the second linearization circuit comprises a second resistor and a second capacitor coupled in series with each other between the third terminal and the fourth terminal.

14. The Doherty amplifier of claim 13, wherein a value of the first resistor is smaller than a value of the second resistor.

15. The Doherty amplifier of claim 1, further comprising a power divider configured to generate the first input RF signal and the second input RF signal based on an input RF signal.

16. The Doherty amplifier of claim 1, wherein
the carrier amplification transistor is biased as Class AB by the carrier bias voltage, and
the peaking amplification transistor is biased as Class C by the peaking bias voltage.

17. A Doherty amplifier, comprising:
a carrier amplification transistor configured to amplify a first input radio frequency (RF) signal;
a first transistor comprising a first terminal configured to supply a carrier bias voltage to the carrier amplification transistor;
a peaking amplification transistor configured to amplify a second input RF signal;
a second transistor comprising a second terminal configured to supply a peaking bias voltage to the peaking amplification transistor; and
a first linearization circuit connected between a terminal to which the second input RF signal is input and the second terminal of the second transistor, and configured to couple a portion of the second input RF signal to the second terminal of the second transistor.

18. The Doherty amplifier of claim 17, further comprising a second linearization circuit connected between a terminal to which the first input RF signal is input and the first terminal of the first transistor, and configured to couple a portion of the first input RF signal to the first terminal of the first transistor.

19. The Doherty amplifier of claim 18, wherein
the first linearization circuit comprises a first resistor and a first capacitor coupled in series with each other between the terminal to which the second input RF signal is input and the second terminal of the second transistor, and
the second linearization circuit comprises a second resistor and a second capacitor coupled in series with each other between the terminal to which the first input RF signal is input and the first terminal of the first transistor.

20. The Doherty amplifier of claim 19, wherein a value of the first resistor is smaller than a value of the second resistor.
